(19) United States
(12) Patent Application Publication
(10) Pub. No.: US 2026/0058637 A1
(43) Pub. Date: Feb. 26, 2026

(54) MICRO/NANO ELECTROMECHANICAL RING OSCILLATOR DEVICE

(71) Applicant: Indian Institute of Science, Kamataka (IN)

(72) Inventors: Disha Chugh, Bengaluru (IN); Saurabh A. Chandorkar, Bengaluru (IN)

(73) Assignee: Indian Institute of Science, Kamataka (IN)

(21) Appl. No.: 19/310,175

(22) Filed: Aug. 26, 2025

(30) Foreign Application Priority Data
Aug. 26, 2024 (IN) 202441064303

(51) Int. Cl. H03H 9/24; H03H 9/02; H03H 9/66

(52) U.S. Cl. CPC H03H 9/2431; H03H 9/02259; H03H 9/2426; H03H 9/2473; H03H 9/66

(57) ABSTRACT

The present disclosure discloses a capacitively transduced Micro or Nano Electromechanical ring oscillator device comprising two or more resonance units coupled with each other, the two or more resonance units are coupled with one or more Signal Conditioning Circuits (SCCs). The oscillator further comprises a first set of the one or more SCC is coupled with at least one of the two or more resonance units. Further, the oscillator comprises a second set of the one or more SCC is coupled with at least one of the two or more resonance units, wherein one of the first set of the one or more SCC and the second set of the one or more SCC is configured to operate in a buffer active state. The two or more resonance units comprises one or more control gate units, and the two or more resonance units are coupled with each other in a back-to-back configuration.

### TECHNICAL FIELD

Aspects of the present disclosure relate generally to micro/nano electromechanical system (MEMS/NEMS) devices, and more particularly, but not by way of limitation, present subject matter relates to a ring oscillator device formed from a capacitively-transduced Micro/Nano electromechanical resonator.

### BACKGROUND

Ring oscillators are components utilized for producing oscillations by utilizing a series of inverters or other suitable logic gates which are arranged in a closed loop. A signal can continuously propagate around the loop, such that a periodic oscillation is created. Ring oscillators are generally used in applications, such as frequency synthesis, clock signal generation, and so on. Ring oscillators are generally fabricated from electronic oscillator circuits. Generally, electronic components, such as operational amplifiers (Op-Amp) or transistors serve as the amplifying active element in the amplifier, and the back-fed in-phase signal is what keeps the oscillations going by compensating for the circuit's losses.

However, the ring oscillators based on electronic oscillator circuits and/or electronic components typically exhibits higher phase noise due to various factors like thermal agitation, power supply fluctuations, and component imperfections. Said noise, in turn, degrades overall performance of the application, in which such oscillators are being used. Further, such oscillators, based on existing technologies, comprise a limited frequency due to the propagation delay of the components, such as inverters, and a number of stages included in such oscillators. Therefore, achieving very high or very low frequencies using such oscillators, without compromising on the overall performance is challenging. Furthermore, in order to address the above-stated issues, a very high complex design of such oscillator is required.

Existing ring oscillators exhibit poor phase noise performance compared to typical L-C based oscillator configurations. Furthermore, these oscillators are limited in their capability to generate high frequency outputs.

In the existing technologies, quartz oscillators are the most commonly used devices for applications needing superior noise-performance. For example, for high frequency clocks, a Phase Locked Loop (PLL) based circuit is necessary for achieving better performance compared to L-C based oscillators. However, these devices are bulky, limited to low frequencies, incapable of being fully integrated with standard CMOS circuitry, and have poorer-long term stability.

Thus, there is a requirement of compact, power efficient, low phase noise, high frequency, CMOS integrable, and high long-term stability oscillators which eliminates the need for additional signal conditioning circuits with reduced noise.

The information disclosed in this background of the disclosure section is only for enhancement of understanding of the general background of the invention and should not be taken as an acknowledgement or any form of suggestion that this information forms the prior art already known to a person skilled in the art.

### SUMMARY

The purpose of this summary is to present a few concepts in an easy-to-understand manner. These concepts are further explained in the invention's thorough description. This synopsis is not meant to define the invention's scope or to highlight its most important or creative concepts.

In an embodiment, the present disclosure discloses a capacitively transduced Micro or Nano Electromechanical ring oscillator device comprising two or more resonance units coupled with each other, the two or more resonance units are coupled with one or more Signal Conditioning Circuits (SCCs). The oscillator device further comprises a first set of the one or more SCC is coupled with at least one of the two or more resonance units. Further, the oscillator comprises a second set of the one or more SCC is coupled with at least one of the two or more resonance units, wherein one of the first set of the one or more SCC and the second set of the one or more SCC is configured to operate in a buffer active state. The two or more resonance units comprises one or more control gate units, and the two or more resonance units are coupled with each other in a back-to-back configuration.

In another embodiment, the present disclosure discloses a method of operating a capacitively transduced Micro or Nano Electromechanical ring oscillator device, the capacitively transduced Micro or Nano Electromechanical ring oscillator comprising two or more resonance units electrically coupled with each other, the two or more resonance units are electrically coupled with one or more Signal Conditioning Circuits (SCCs). The method comprising coupling a first set of the one or more SCC with at least one of the two or more resonance units. The method further comprising coupling a second set of the one or more SCC with at least one of the two or more resonance units, wherein one of the first set of the one or more SCC and the second set of the one or more SCC is configured to operate in a buffer active state. Further, the two or more resonance units comprises one or more control gate units, and the two or more resonance units are coupled with each other in a back-to-back configuration.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the drawings, which are not necessarily drawn to scale, like-numerals describe substantially similar components throughout the several views. Like-numerals having different letter suffixes represent different instances of substantially similar components. The drawings illustrate generally, by way of example, but not by way of limitation, one or more embodiments are now described, by way of example only, with reference to the accompanying drawings in which:

FIG. 1 illustrates a block diagram of a capacitively transduced Micro or Nano Electromechanical ring oscillator device, in accordance with some embodiments of the present disclosure.

FIG. 2 illustrates a schematic diagram of a capacitive transduced MEMS resonator, in accordance with some embodiments of the present disclosure.

FIG. 3 illustrates a schematic diagram of a Single Input Single Output (SISO) ring oscillator device made from capacitive MEMS/NEMS resonators, in accordance with some embodiments of the present disclosure.

FIG. 4 illustrates a schematic diagram of an output circuit which follows the oscillator device loop presented in FIG. 2, in accordance with some embodiments of the present disclosure.

FIG. 5 illustrates a schematic diagram of a Multiple Input Multiple Output (MIMO) capacitive MEMS/NEMS ring oscillator device, in accordance with some embodiments of the present disclosure.

FIG. 6 illustrates a schematic diagram of an output circuit which may follow the circuit shown in FIG. 4, in accordance with some embodiments of the present disclosure.

FIGS. 7, 8, 9, 10, 11 illustrate different schematic diagrams for ring oscillators made from capacitive Double Ended Tuning Fork (DETF) resonators, in accordance with various embodiments of the present disclosure.

FIG. 12 illustrates a schematic diagram of the output circuit which can be used in conjunction with any of the outputs of oscillators of FIGS. 7, 8, 9, 10, 11, in accordance with various embodiments of the present disclosure.

FIG. 13 illustrates a flow chart of a method for operating a capacitively transduced Micro or Nano Electromechanical ring oscillator, in accordance with some embodiments of the present disclosure.

The figures depict embodiments of the disclosure for purposes of illustration only. One skilled in the art will readily recognize from the following description that alternative embodiments of the structures and methods illustrated herein may be employed without departing from the principles of the disclosure described herein.

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included with in the spirit and scope of the invention as defined by various embodiments.

In the following description, numerous specific details are set forth in order to provide a thorough understanding of the present subject matter. Particular example embodiments of the present subject matter may be implemented without some or all of these specific details. In other instances, well known process operations have not been described in detail in order not to unnecessarily obscure the present subject matter.

Various techniques and mechanisms of the present subject matter will sometimes be described in singular form for clarity. However, it should be noted that some embodiments include multiple iterations of a technique or multiple instantiations of a mechanism unless noted otherwise.

The terms “comprises”, “comprising”, or any other variations thereof, are intended to cover a non-exclusive inclusion, such that a setup, device or method that comprises a list of components or steps does not include only those components or steps but may include other components or steps not expressly listed or inherent to such setup or device or method. In other words, one or more elements in a device or system or apparatus proceeded by “comprises . . . a” does not, without more constraints, preclude the existence of other elements or additional elements in the device or system or apparatus.

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to” unless expressly specified otherwise.

Various embodiments of the present disclosure relate to novel Micro/Nano electromechanical ring oscillator device. Specifically, the present subject matter relates to an oscillator formed by connecting two or more electrostatically transduced micro and/or nano electromechanical resonators. Further, the present disclosure relates to ring oscillators using resonators and various input output configurations for flexible and efficient performance of ring oscillators. By adjusting these configurations, optimization of phase relation and frequency stabilization can be achieved thereby providing precise phase differences and frequency references.

In view of the above, present subject matter uses MEMS/NEMS resonators in place of traditional electronic components. These resonators are capable of narrow-band amplification and can be arranged in a ring configuration to achieve necessary phase differences for oscillation. This approach allows for more compact power efficient, and potentially high frequency oscillators. Also, by leveraging the natural amplification properties of electro-mechanical resonators (at the natural/resonant frequencies) thereby reducing the noise, the design can simplify, even eliminate the need for additional signal conditioning circuits, further enhancing the efficiency of the oscillator.

The fundamental concept of the present subject matter is that the resonators can be used as amplifiers in a narrowband and can be utilized to create self-oscillating circuits. In some embodiments of the present subject matter, for the ring oscillator to function properly, the phase of the final fed-back signal should be a multiple of 21, meeting the Barkenhausen criterion for oscillations.

However, conventionally, a ring oscillator cannot be made purely using Micro/Nano electromechanical resonator unless a resonator is capable of signal/power amplification.

The present disclosure discloses a ring oscillator formed by connecting two or more electrostatically transduced micro and/or nano electromechanical resonators in a back-to-back configuration with optional intermediate signal conditioning circuits.

The method of such a ring oscillator includes feeding one or more floating gate voltage outputs from one resonator as an input to one or more electrodes of another second resonator. Subsequently, output voltages from one or more floating gate electrodes are either fed back to original resonator or to the next resonator to eventually complete a loop back to the starting resonator. In an embodiment, the ring oscillators utilizing capacitive MEMS/NEMS resonators can be implemented with or without interfacing signal conditioning circuits including, but not limited to, individual or combination thereof buffers, amplifiers, phase shifters, automatic gain controller, non-linear element for limiting voltage etc.

A preferred embodiment includes a generic topology including the case when only two resonators are feeding each other with no interface circuit, thereby leveraging their inherent amplification capabilities.

In one preferred embodiment, the resonator (also referred hereinafter and in the figures as resonator system) maybe but not limited to Double-ended-tuning-fork (DETF) resonator.

In an embodiment, each resonator may be representative of a resonator system comprising of multiple resonators and each resonator can have multiple DC supplies connected to it.

The resonator, as per the present subject matter, may be a mechanical resonator representative of a device capable of transforming energy from a potential energy into a kinetic energy and transforming the kinetic energy into the potential energy in an oscillatory manner/fashion. Herein, in the context of the present subject matter, the term ‘resonator’ is also interchangeably used to refer to ‘the resonator system’. For example, the resonator system comprises the resonator and one or more components and/or electrodes that aid in capacitive transduction of the mechanical resonator. For example, the one or more components and/or electrodes are made to resonate with the input electrical signals. Examples of the one or more components and/or electrodes may include, but are not limited to, actuation electrodes, sensing electrodes, tuning electrodes, and biasing electrodes. A person skilled in the art will appreciate that the resonator system, in accordance with various embodiments of the present subject matter, may include other components, electrodes, and/or sub-systems which are necessarily required to bias, actuate, and sense a resonant behaviour. In the present disclosure, the objective in which the term ‘the resonator’ is used can be inferred from the context in which it is used.

In one particular embodiment, the oscillator topology allows for each resonator to operate at different phases in such a way that the overall phase of the input signal returning to a node in the oscillator loop is 2π. In another embodiment, overall phase in the oscillator can be 2nπ, where n lies in the interval 1≤n≤N and N is any natural number.

In another embodiment, an oscillator topology consists of a single device composed of many coupled resonators where-in the displacements of each resonator can be at a different phase with respect to the other resonator and the ring oscillator configuration is formed using one or more resonators of the same device with appropriate phase difference between them.

In an embodiment, resonator could include one or more MEMS/NEMS resonators, coupled together with each other mechanically. In another embodiment, resonator could include one or more micro/nano electromechanical resonators, coupled together with each other electrically.

In an embodiment, minimum of two resonators are required for ring oscillator device. However, the present subject matter is not restrictive to only two ring resonators. Accordingly, a person skilled in the art may appreciate that the present subject matter may be implemented utilizing more number of resonators also.

In a preferred embodiment, resonators have similar resonant frequencies with overlapping 3 dB bandwidth (at the frequency of oscillation). In an embodiment, ring oscillators may include Bias/Bias tuning/stray charge compensating electrodes and voltages. In an embodiment, electrodes can be grounded. In another embodiment, electrodes can be kept at any desired potential. In another embodiment, electrodes can be left electrically floating. In a preferred embodiment, it is possible to simultaneously achieve multiple frequencies at the output of such a MEMS/NEMS ring oscillator device. In another embodiment, desired number of inputs and outputs from a resonator/amplifier/buffer/signal conditioning circuit, can be implemented.

In an embodiment, number of inputs and outputs to a subsystem need not be equal. In an embodiment, resonators of the ring oscillator may include tuneable voltages. In an embodiment, any number of electrodes can be left electrically floating in any subsystem of the ring oscillator. In an embodiment, different physical configurations are possible for every resonator. In another embodiment, different electrical configurations are possible for every resonator.

In an embodiment, the configuration may include outer-outer and outer-outer (O-O O-O) configuration. In another embodiment, the configuration may include inner-outer and outer-outer (I-O O-O) configuration. Yet in another embodiment, the configuration may include inner-outer and inner-outer (I-O I-O) configuration. Yet in another embodiment, the configuration maybe inner-inner and inner-inner (I-I I-I) configuration. Yet in another embodiment, the system maybe multi-input multi-output system and the configuration may be outer-inner, inner-outer, outer-inner, and inner-outer (O-I I-O O-I I-O) configuration. The above-stated various configurations are further described in detail with respect to the FIGS. 6-10.

In an embodiment, an output circuit is disclosed which follows an output from the MEMS/NEMS ring oscillator device. MEMS oscillators, as per the present subject matter, are electro-mechanical devices that provide superior long-term drift performance, higher quality factors, higher achievable frequencies all the way up to GHz range along with possible integration with standard Complementary Metal-Oxide-Semiconductor (CMOS) electronics.

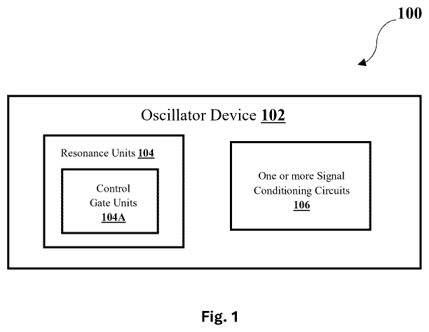

Various configurations are described in detail with reference to FIGS. 1 to 11. Glossary of terms, respective nomenclature, and representation information pertaining to various circuit elements in the circuit representation, as illustrated in FIGS. 1 to 11, are disclosed in a glossary included in a tabular form at the end of the present disclosure, and the same is not included in respective description of each figure for the sake of brevity.

FIG. 1 illustrates a block diagram of a capacitively transduced Micro or Nano Electromechanical ring oscillator device, in accordance with some embodiments of the present disclosure.

As shown in FIG. 1, the block diagram 100 of capacitively transduced Micro or Nano Electromechanical ring oscillator device is disclosed. The block diagram 100 depicts an oscillator device 102 comprising a resonance unit 104 and one or more signal conditioning circuits 106, which may be coupled mechanically and/or electrically to perform the one or more desired functions of the present disclosure. In some embodiments, the resonance unit 104 and the one or more signal conditioning circuits 106 may be communicatively coupled to perform the one or more desired functions of the present disclosure. The resonance units 104 may further comprise control gate units 104A. In a non-limiting example, resonance units 104 may comprise two or more resonance units. In some non-limiting embodiment, the resonance units 104 may include one or more resonators, one or more actuators, one or more sensing units. For example, the one or more actuating units may include one or more actuators, the one or more sensing units may include one or more sensing electrodes.

In a non-limiting embodiment, the oscillator device 102 may be a capacitively transduced Micro or Nano Electromechanical ring oscillator. The two or more resonance units may be coupled with each other, the two or more resonance units may further be coupled with one or more Signal Conditioning Circuits (SCCs). The two or more resonance units may be configured to operate as at least one of a resonator, a signal amplifier, a signal limiting unit, and a phase shifting unit. Further, each of the two or more resonance units may be configured to receive one or more input signals and may provide one or more output signals, the two or more resonance units may be connected with the one or more SCCs may operate at different phases, an overall phase of input signal returning to the first resonance unit in the ring oscillator device may be an integer multiple of 2π. A first set of the one or more SCC may be coupled with at least one of the two or more resonance units. Further, a second set of the one or more SCC may be coupled with at least one of the two or more resonance units, one of the first set of the one or more SCC and the second set of the one or more SCC may be configured to operate in a buffer active state, the two or more resonance units may comprise one or more control gate units, and the two or more resonance units may be coupled with each other in a back-to-back configuration.

In yet another embodiment, the one or more control gate units may receive input with one or more tuneable power sources which may be actively controlled based on signals sensed from one or more resonance units, and the one or more SCCs may include at least one of a buffer, an amplifier, a phase shifter, an automatic gain controller, a non-linear element for limiting the one or more sensing unit outputs. Further, the two or more resonating units may be configured to operate at multiple resonant frequencies, an output of the ring oscillator may comprise the multiple resonant frequencies, and the two or more resonators may be configured to operate at resonant frequencies within an overlapping 3 dB bandwidth.

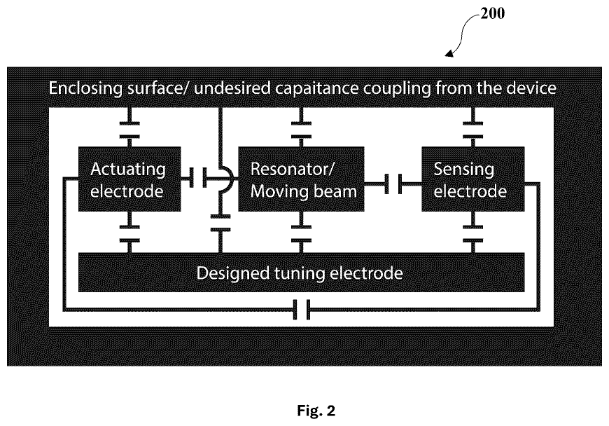

FIG. 2 illustrates a schematic diagram of a capacitive MEMS resonator 200, in accordance with an embodiment of the present disclosure. In an embodiment, the capacitive MEMS resonator 200 may be a capacitive air/vacuum/dielectric-gap-closing MEMS resonator. The capacitive MEMS resonator 200 may also be referred hereinafter, in the present disclosure, as a MEMS resonator or a MEMS device. In some embodiments, the capacitive air/vacuum/dielectric-gap-closing MEMS resonator includes an actuation electrode (also referred hereinafter and in figures as actuating electrode), a resonator or a moving beam, a sensing electrode (also referred hereinafter and in figures as sense electrode), a designed tuning electrode, electrically-floating electrode, and an enclosing surface. The enclosing surface may be composed of same or different material at different spatial positions around the resonator system. The MEMS device may implement voltage-sensing on electrically-floating electrical node, such as resonator, using bias-tuning/compensating/gate/secondary electrodes. In some embodiments, the bias-tuning/compensating/gate/secondary electrode may be capacitively coupled with the electrically-floating electrode. The control signal for the bias-tuning/compensating/gate/secondary electrode may be obtained using a feedback circuit (not shown).

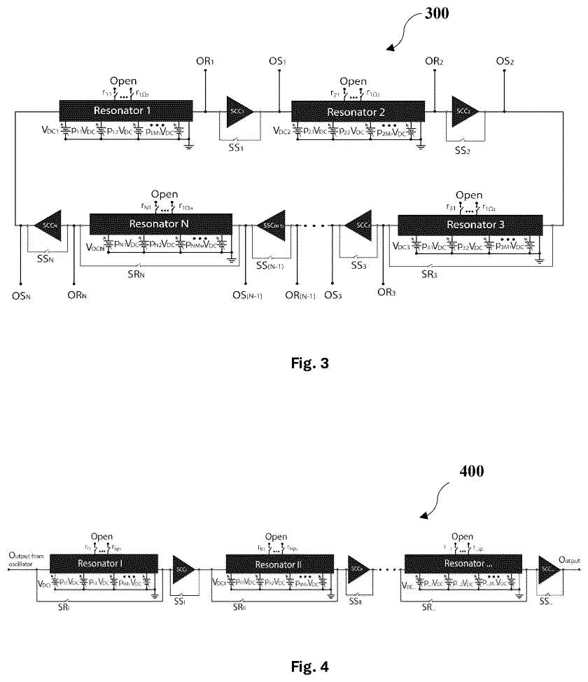

Referring now to FIG. 3, a schematic diagram of a Single Input Single Output (SISO) ring oscillator device 300 made from capacitive MEMS/NEMS resonators is illustrated, in accordance with some embodiments of the present disclosure. The illustrated figure may relate to a ring oscillator device with MEMS/NEMS resonators interconnected with signal conditioning circuits. The signal conditioning circuits may include (voltage/power) amplifier with desired gain and phase, buffer (current/voltage/power), non-linear elements, such as limiter circuit, Automatic Gain Control (AGC) circuits, etc. at output of each resonator. The configuration disclosed in reference to FIG. 3 is SISO (Single Input Single Output) configuration.

In some embodiments, a number of inputs and outputs to a subsystem of FIG. 3 need not be equal. Each subsystem and each resonator may have multiple DC supplies connected to it. Also, it is possible that every resonator may have a different physical and electrical configuration. In addition, any number of electrodes in the oscillator device may be left electrically floating in any subsystem.

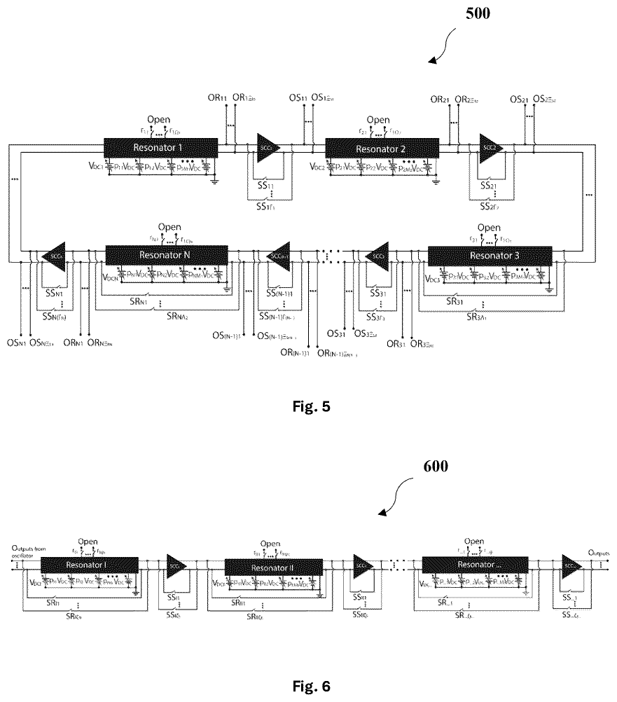

FIG. 4 illustrates a schematic diagram 400 of an output circuit which may follow the oscillator loop presented in FIG. 3, in accordance with some embodiments of the present disclosure. The circuit may consist of a combination of MEMS/NEMS resonator-based amplifiers as well as the optional signal conditioning circuits. Each resonator may comprise of multiple resonators, and each resonator can have multiple DC supplies connected to it. Input to this system (terminal: output from oscillator) may be connected to any of the output terminals described in FIG. 3. The configuration disclosed herein is in accordance to FIG. 3 i.e. SISO (Single Input Single Output) configuration.

In some embodiments, it may be possible that every resonator has a different physical/mechanical and electrical configuration, and any number of electrodes can be left electrically floating in any subsystem.

FIG. 5 illustrates a schematic diagram 500 of a Multiple Input Multiple Output (MIMO) capacitive MEMS/NEMS ring oscillator device, in accordance with some embodiments of the present disclosure. The configuration disclosed in reference to FIG. 5 is MIMO (Multiple Input Multiple Output) configuration.

In some embodiments, the number of inputs and outputs of each sub-system may be unequal. In addition, each subsystem and each resonator can have multiple DC supplies connected to it. Also, it is possible that every resonator has a different physical and electrical configuration. In addition, any number of electrodes may be left electrically floating in any subsystem as disclosed in the description of FIG. 3.

FIG. 6 illustrates a schematic diagram 600 of an output circuit which may follow the circuit shown in FIG. 5, in accordance with some embodiments of the present disclosure. The circuit consists of a combination of MEMS/NEMS resonator-based amplifiers as well as the optional signal conditioning circuits similar to the FIG. 4. Input to the system (terminals: outputs from oscillator) as disclosed in FIG. 6 may be connected to any of the output terminals described in FIG. 4.

In some embodiments, each resonator of the FIG. 6 may comprise multiple resonators and each resonator can have multiple DC supplies connected to it. Also, it is possible that every resonator has a different physical and electrical configuration. In addition, number of electrodes can be left electrically floating in any subsystem.

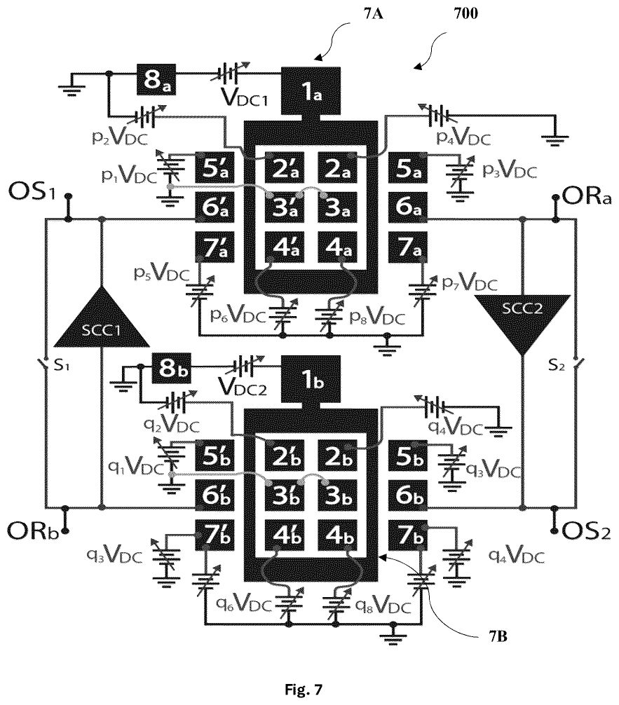

FIG. 7 illustrates a schematic diagram 700 for a ring oscillator device made from capacitive Double Ended Tuning Fork (DETF) resonators, in accordance with an embodiment of the present disclosure.

In FIG. 7, Double Ended Tuning Fork resonators 7A and 7B may be connected back-to-back with optional signal conditioning circuits in between. Example configuration disclosed in FIG. 7 is O-O O-O configuration which means outer-outer (6ₐ′ to 6_{b}′) and outer-outer (6ₐ to 6_{b}) electrodes of the DETF resonators of the ring oscillator are connected. The nomenclature and representation information pertaining to the circuit elements, illustrated in FIGS. 7-12, can be referred from the glossary provided and the end of the present disclosure.

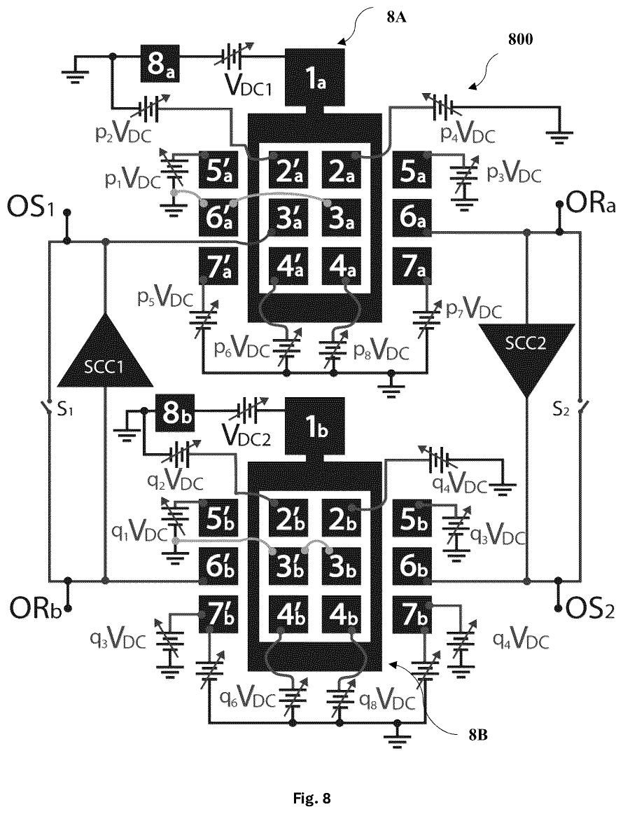

FIG. 8 illustrates a schematic diagram 800 of MEMS/NEMS ring oscillator device with two DETF resonators 8A and 8B, in accordance with an embodiment of the present disclosure. As per FIG. 8, the two DETF resonators are connected back-to-back with optional signal conditioning circuits in between.

Another preferred example embodiment of FIG. 8 discloses an I-O O-O configuration means that inner-outer (3ₐ′ to 6_{b}′) and outer-outer (6ₐ to 6_{b}) electrodes of the DETF resonators in ring oscillator connected.

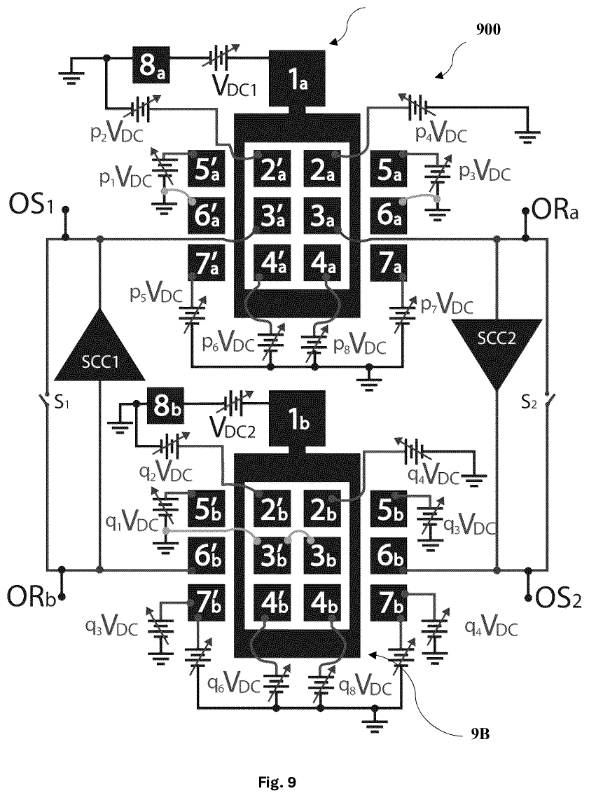

FIG. 9 illustrates a schematic diagram 900 of MEMS/NEMS ring oscillator device with two DETF resonators 9A and 9B, in accordance with an embodiment of the present disclosure. As per FIG. 8, the two DETF resonators are connected back-to-back with optional signal conditioning circuits in between with example of I-O I-O configuration i.e. inner-outer (3ₐ′ to 6_{b}′) and inner-outer (3ₐ to 6_{b}) electrodes of the DETF resonators in ring oscillator connected.

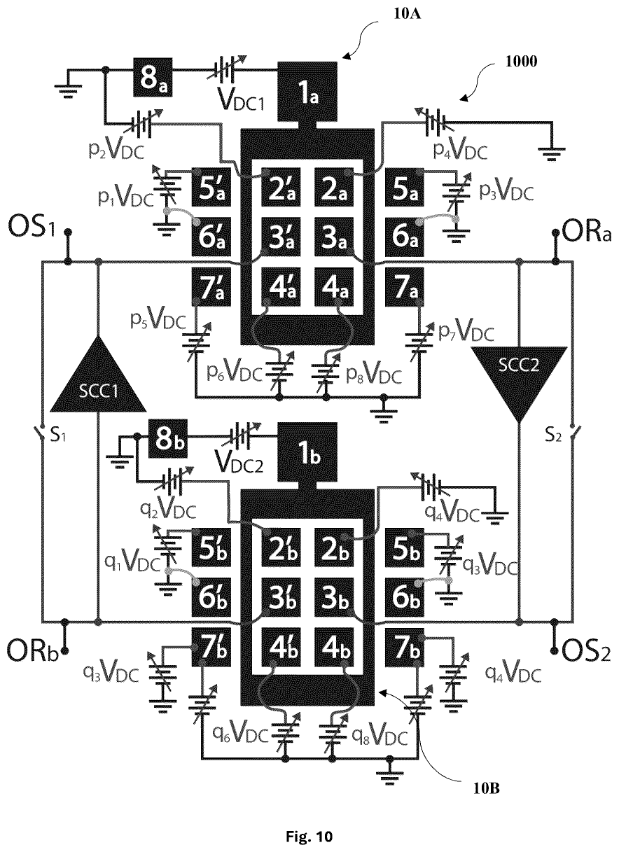

FIG. 10 illustrates a schematic diagram 1000 of MEMS/NEMS ring oscillator device with two DETF resonators, 10A and 10B in accordance with an embodiment of the present disclosure. As per FIG. 10, the two DETF resonators are connected back-to-back with optional signal conditioning circuits in between with an example of I-I I-I configuration i.e. inner-inner (3ₐ′ to 3_{b}′) and inner-inner inner-inner (3ₐ to 3_{b}) electrodes of the DETF resonators in ring oscillator are connected.

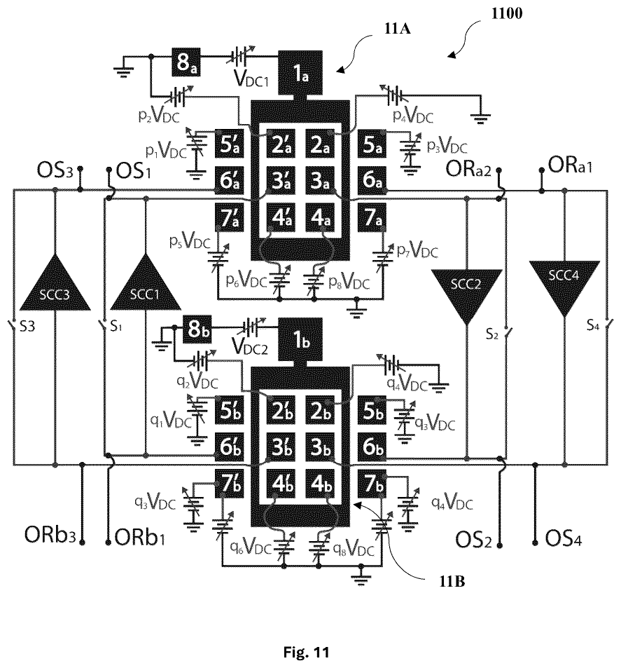

FIG. 11 illustrates a schematic diagram 1100 of a MEMS/NEMS ring oscillator device with two DETF resonators 11A and 11B. As per FIG. 11, the two DETF resonators are connected back-to-back with optional signal conditioning circuits in between, and FIG. 11 illustrates a multi-input multi-output system whereby each resonator has two inputs and two outputs. In this example, the configuration of connection between the two resonators is given by O-I I-O O-I I-O, i.e. inner electrode 3ₐ′ is connected to 6_{b}′, inner electrode 3_{b}′ is connected to 6ₐ′, inner electrode 3ₐ is connected to 6_{b}, and inner electrode 3_{b} is connected to 6ₐ.

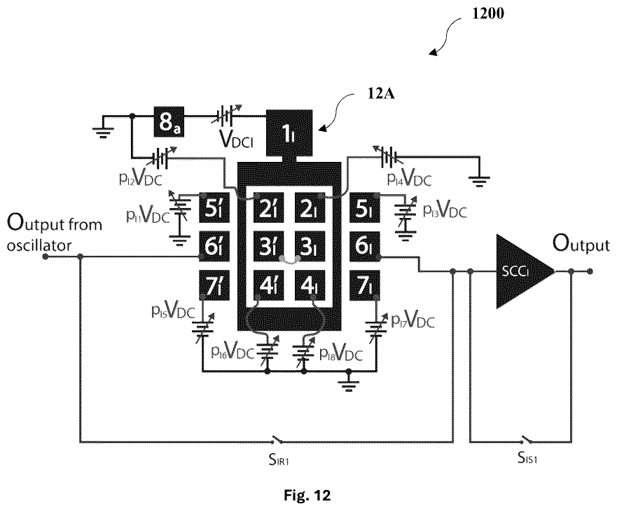

FIG. 12 illustrates a schematic diagram 1200 of the output circuit which can be used in conjunction with any of the oscillators of FIG. 7, 8, 9, 10, or 11 in accordance with various embodiments of the present disclosure.

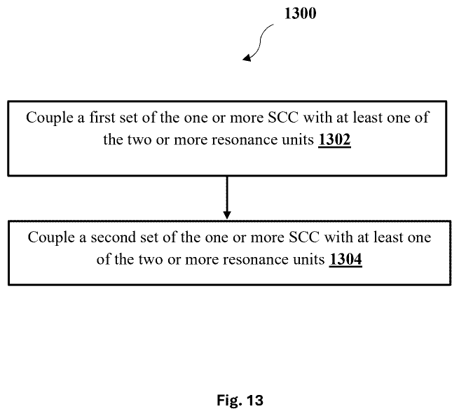

FIG. 13 illustrates a flow chart of a method for operating a capacitively transduced Micro or Nano Electromechanical ring oscillator device, in accordance with some embodiments of the present disclosure.

FIG. 13 represents a process flow 1300 of an exemplary method for operating a capacitively transduced Micro or Nano Electromechanical ring oscillator device. The order in which the process 1300 is described is not intended to be construed as a limitation, and any number of the described process blocks may be combined in any order to implement the process. Additionally, individual blocks may be deleted from methods without departing from the spirit and scope of the subject matter described. Furthermore, the process can be implemented in any suitable hardware and mechanical components. However, for ease of explanation, in the embodiments described below, the process 1300 may be considered to be implemented by the oscillator device 102 of FIG. 1.

At step 1302, the process 1300 may include method of operating a capacitively transduced Micro or Nano Electromechanical ring oscillator device, the capacitively transduced Micro or Nano Electromechanical ring oscillator device comprising two or more resonance units electrically coupled with each other, the two or more resonance units are electrically coupled with one or more Signal Conditioning Circuits (SCCs), coupling a first set of the one or more SCC with at least one of the two or more resonance units, as discussed in earlier embodiments of FIGS. 1-12.

At step 1304, the process 1300 may include coupling a second set of the one or more SCC with at least one of the two or more resonance units, wherein one of the first set of the one or more SCC and the second set of the one or more SCC is configured to operate in a buffer active state, the two or more resonance units comprises one or more control gate units, and the two or more resonance units are coupled with each other in a back-to-back configuration, as discussed in earlier embodiments of FIGS. 1-12.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed.

Alternatives will be apparent to persons skilled in the relevant art(s) based on the teachings contained herein. Such alternatives fall within the scope and spirit of the disclosed embodiments.

The configurations and electrode patterns described above lead to more efficient noise reduction and production of more stable oscillations, contributing to the overall performance and reliability of the system.

In yet another non-limiting embodiment, an oscillator device may be formed by connecting two or more electrostatically transduced micro and/or nano electromechanical resonators in a back-to-back configuration whereby one or more floating gate voltage outputs from a resonator is/are may be fed as an input to one or more electrodes on a second resonator with optional intermediate signal conditioning circuits including, but not limited to, individual or combination thereof buffers, amplifiers, phase shifters, automatic gain controller, non-linear element for limiting voltage etc. Subsequently, output voltages from one or more floating gate electrodes may be either fed back to original resonator or to the next resonator to eventually complete a loop back to the starting resonator. Further, the oscillator device topology may allow for each resonator to operate at different phases in such a way that the overall phase of the input signal returning to a node in the oscillator loop is 2π.

In yet another non-limiting embodiment, an oscillator device topology may consist of a single device composed of many coupled resonators where-in the displacements of each resonator may be at a different phase with respect to the other resonator and the ring oscillator configuration may be formed using one or more resonators of the same device with appropriate phase difference between them. The ring oscillator may optionally include suitable circuitry as shown in the embodiment of single input or multi-input Mems/Nems ring oscillator arrangement shown in FIG. 3, FIG. 4, and FIG. 5. Further, an embodiment of a resonator could include one or more micro/nano electromechanical resonators, coupled together with each other either mechanically or electrically. It may be possible to simultaneously achieve multiple frequencies at the output of such a MEMS/NEMS ring oscillator.

The present subject matter, based on the above-mentioned embodiments, thus, discloses design and implementation of such ring oscillators using MEMS/NEMS resonators for efficient and compact oscillation generation by harnessing unique properties of MEMS/NEMS resonators.

In yet another non-limiting embodiment, a capacitively transduced Micro or Nano Electromechanical ring oscillator device may comprise two or more resonance units coupled with each other, the two or more resonance units are coupled with one or more Signal Conditioning Circuits (SCCs). Further, the oscillator device may comprise a first set of the one or more SCC is coupled with at least one of the two or more resonance units and a second set of the one or more SCC is coupled with at least one of the two or more resonance units, wherein one of the first set of the one or more SCC and the second set of the one or more SCC is configured to operate in a buffer active state. The two or more resonance units may comprise one or more control gate units, and the two or more resonance units are coupled with each other in a back-to-back configuration. Further, the two or more resonance units may be configured to operate as at least one of a resonator, a signal amplifier, a signal limiting unit, and a phase shifting unit.

In yet another non-limiting embodiment, the each of the two or more resonance units may be configured to receive one or more input signals and provide one or more output signals, the two or more resonance units connected with the one or more SCCs may operate at different phases, an overall phase of input signal returning to the first resonance unit in the ring oscillator is an integer multiple of 2π. Further, the one or more control gate units may input with one or more tuneable power sources which are actively controlled based on signals sensed from one or more resonance units, and the one or more SCCs includes at least one of a buffer, an amplifier, a phase shifter, an automatic gain controller, a non-linear element for limiting the one or more sensing unit outputs. The two or more resonating units may be configured to operate at multiple resonant frequencies, an output of the ring oscillator comprises the multiple resonant frequencies, and the two or more resonators are configured to operate at resonant frequencies within an overlapping 3 dB bandwidth.

The illustrated configurations and functionalities are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open ended in that an item or items following any one of these words is not meant to be an exhaustive listing of such item or items or meant to be limited to only the listed item or items. It must also be noted that as used herein, the singular forms “a,” “an,” and “the” include plural references unless the context clearly dictates otherwise.

Finally, the language used in the specification has been principally selected for readability and instructional purposes, and it may not have been selected to delineate or circumscribe the inventive subject matter. Accordingly, the disclosure of the embodiments of the disclosure is intended to be illustrative, but not limiting, of the scope of the disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

### Tabular Representation of Schematics and Associated Description for One or More of the FIGS. 1-13

Glossary for oscillator schematics

| | |
|---|---|
| V_{DCi}, | Bias voltage for ith resonator |
| i ϵ [symbol] , | |
| 1 ≤ i ≤ N | |
| pᵢⱼV_{DC}, | Tuneable DC voltages in resonator ‘N’ |
| i, j ϵ [symbol] , | N = Nth resonator in the ring oscillator |
| 1 ≤ i ≤ N | |
| 1 ≤ j ≤ M_{N} | |
| SSᵢⱼ | Switch across Signal Conditioning Circuit |
| i, j ϵ [symbol] , | N = Nth resonator in the ring oscillator |
| 1 ≤ i ≤ N | |
| 1 ≤ j ≤ Γ_{N} | |
| SRᵢⱼ | Switch across Resonator |
| i, j ϵ [symbol] , | N = Nth resonator in the ring oscillator |
| 3 ≤ i ≤ N, | |
| 1 ≤ j ≤ Λ_{N} | |
| rᵢⱼ | Electrically floating electrodes |
| i, j ϵ [symbol] , | N = Nth resonator in the ring oscillator |
| 1 ≤ i ≤ N | |
| 1 ≤ j ≤ Ω_{N} | |
| ORᵢ | ith output terminal following the ith resonator in the SISO (Single Input |
| i ϵ [symbol] , | Single Output) oscillator loop |
| 1 ≤ i ≤ N | |
| OSᵢ | ith output terminal following the ith signal condition circuit in the SISO |
| i ϵ [symbol] , | (Single Input Single Output) oscillator loop |
| 1 ≤ i ≤ N | N = Nth Signal conditioning circuit (SCC) in the ring oscillator |
| ORᵢⱼ | i j th output terminal following the ith resonator in the oscillator loop |
| i, j ϵ [symbol] , | N = Nth resonator in the ring oscillator |
| 1 ≤ i ≤ N | |
| 1 ≤ j ≤ Ξ_{Ri} | |
| OSᵢⱼ | i j th output terminal following the ith Signal conditioning circuit (SCC) |
| i, j ϵ [symbol] , | in the oscillator loop |
| 1 ≤ i ≤ N | N = Nth resonator in the ring oscillator |
| 1 ≤ j ≤ Ξ_{Si} | |

Glossary for output circuits

| | |
|---|---|
| Resonatorᵢ | ith resonator following output terminal of the oscillator |
| i ϵ [symbol] , | |
| I ≤ i ≤ . . . | |
| SRᵢ | ith switch across the ith resonator in the output circuit for the SISO |
| i ϵ [symbol] , | (Single Input Single Output) oscillator |
| I ≤ i ≤ . . . | |
| SSᵢ | ith switch across the ith Signal conditioning circuit (SCC) in the output |
| i ϵ [symbol] , | circuit for the SISO (Single Input Single Output) oscillator |
| I ≤ i ≤ . . . | |
| SRᵢⱼ | i j th switch across the ith resonator in the output circuit for the MIMO |
| i, j ϵ [symbol] , | (Multiple Input Multiple Output) oscillator |
| I ≤ i ≤ N | |
| 1 ≤ j ≤ ζ_{Ri} | |
| SSᵢⱼ | i j th switch across the ith Signal conditioning circuit (SCC) in output |
| i, j ϵ [symbol] , | circuit for MIMO (Multiple Input Multiple Output) oscillator |
| I ≤ i ≤ N | |
| 1 ≤ j ≤ ζ_{Si} | |
| rᵢⱼ | Electrically floating electrodes in the output circuits |
| i, j ϵ [symbol] , | |
| I ≤ i ≤ . . . | |
| 1 ≤ j ≤ φ . . . | |

Glossary for example schematics

| | |
|---|---|
| SCCᵢ | ith Signal Conditioning Circuit |
| i ϵ [symbol] , | |
| 1 ≤ i ≤ N | |
| V_{DC1} | Bias voltage for resonator ‘a’ |
| V_{DC2} | Bias voltage for resonator ‘b’ |
| pᵢV_{DC}, | Tuneable DC voltages for biasing electrodes in resonator ‘a’ |
| i ϵ [symbol] , | |
| 1 ≤ i ≤ 8 | |
| qᵢV_{DC}, | Tuneable DC voltages for biasing electrodes in resonator ‘b’ |
| i ϵ [symbol] , | |
| 1 ≤ i ≤ 8 | |
| Sᵢ, i ϵ {1, 2} | Switch across amplifier / buffer |

1. A capacitively transduced Micro or Nano Electromechanical ring oscillator device, comprising:
two or more resonance units coupled with each other, the two or more resonance units are coupled with one or more Signal Conditioning Circuits (SCCs);
a first set of the one or more SCC is coupled with at least one of the two or more resonance units; and
a second set of the one or more SCC is coupled with at least one of the two or more resonance units, wherein one of the first set of the one or more SCC and the second set of the one or more SCC is configured to operate in a buffer active state,
wherein,
the two or more resonance units comprises one or more control gate units, and the two or more resonance units are coupled with each other in a back-to-back configuration.

2. The oscillator device as claimed in claim 1, wherein two or more resonance units are configured to operate as at least one of a resonator, a signal amplifier, a signal limiting unit, and a phase shifting unit.

3. The oscillator device as claimed in claim 1, wherein each of the two or more resonance units are configured to receive one or more input signals and provide one or more output signals, wherein the two or more resonance units connected with the one or more SCCs operate at different phases, an overall phase of input signal returning to the first resonance unit in the ring oscillator is an integer multiple of 2π.

4. The oscillator device as claimed in claim 1, wherein one or more control gate units are input with one or more tuneable power sources which are actively controlled based on signals sensed from one or more resonance units, and wherein the one or more SCCs includes at least one of: a buffer, an amplifier, a phase shifter, an automatic gain controller, a non-linear element for limiting the one or more sensing unit outputs.

5. The oscillator device as claimed in claim 1, wherein,
the two or more resonating units are configured to operate at multiple resonant frequencies,
an output of the ring oscillator comprises the multiple resonant frequencies, and
the two or more resonators are configured to operate at resonant frequencies within an overlapping 3 dB bandwidth.

6. A method of operating a capacitively transduced Micro or Nano Electromechanical ring oscillator, the capacitively transduced Micro or Nano Electromechanical ring oscillator comprising two or more resonance units electrically coupled with each other, the two or more resonance units are electrically coupled with one or more Signal Conditioning Circuits (SCCs), the method comprising:
coupling a first set of the one or more SCC with at least one of the two or more resonance units; and
coupling a second set of the one or more SCC with at least one of the two or more resonance units, wherein one of the first set of the one or more SCC and the second set of the one or more SCC is configured to operate in a buffer active state,
wherein,
the two or more resonance units comprises one or more control gate units, and the two or more resonance units are coupled with each other in a back-to-back configuration.

7. The method as claimed in claim 6, operating the or more resonance units as at least one of a resonator, signal amplifier, a signal limiting unit, and a phase shifting unit.

8. The method as claimed in claim 6, receiving one or more input signals and providing one or more output signals by each of the two or more resonance units, wherein the two or more resonance units connected with the one or more SCCs operate at different phases, an overall phase of input signal returning to the first resonance unit in the ring oscillator is an integer multiple of 2π.

9. The method as claimed in claim 6, wherein one or more control gate units are input with one or more tuneable power sources which are actively controlled based on signals sensed from one or more resonance units, and wherein the one or more SCCs includes at least one of: a buffer, an amplifier, a phase shifter, an automatic gain controller, a non-linear element for limiting the one or more sensing unit voltage outputs.

10. The method as claimed in claim 6, wherein,
the two or more resonating units are configured to operate at multiple resonant frequencies,
an output of the ring oscillator comprises the multiple resonant frequencies, and
the two or more resonators are configured to operate at resonant frequencies within an overlapping 3 dB bandwidth.
